(19) United States
(12) Patent Application Publication
(10) Pub. No.: US 2026/0121617 A1
(43) Pub. Date: Apr. 30, 2026

(54) DEVICE WITH PIEZOELECTRIC FILM ON SEMICONDUCTOR SUBSTRATE

(71) Applicant: TEXAS INSTRUMENTS INCORPORATED, Dallas, TX (US)

(72) Inventors: Vakhtang CHULUKHADZE, Austin, TX (US); Bichoy BAHR, Allen, TX (US); Udit RAWAT, Allen, TX (US)

(21) Appl. No.: 18/933,703

(22) Filed: Oct. 31, 2024

(51) Int. Cl. H03H 9/58; H03H 3/02; H03H 9/13; H03H 9/60

(52) U.S. Cl. CPC H03H 9/584; H03H 3/02; H03H 9/131; H03H 9/587; H03H 9/60; H03H 2003/021

(57) ABSTRACT

An apparatus includes a die, a bonding layer, and a film. The die includes a semiconductor substrate, a metallization structure on the semiconductor substrate, and a dielectric material around at least a part of the metallization structure. The bonding layer is on the metallization structure. The film is attached on the bonding layer. The film includes a piezoelectric material.

### BACKGROUND

A resonator is a device or system that naturally oscillates at a frequency called a resonant frequency. Resonators can be, for example, crystal resonators (also known as quartz resonators), inductance-capacitance (LC) resonators, or microelectromechanical system (MEMS) resonators. Resonators are generally passive devices that are combined with active circuitry to create an oscillator. The oscillator produces a periodic signal at the resonant frequency. A crystal oscillator, for example, is an electronic circuit that uses the mechanical resonance of a vibrating crystal to create an electrical signal with a very precise frequency. Crystal oscillators may be used to generate frequencies to keep track of time or to generate a clock signal for digital integrated circuits. MEMS resonators may be used in place of crystal resonators to keep track of time and to generate a stable clock signal for analog and digital integrated circuits.

### SUMMARY

In one example, an apparatus includes a die, a bonding layer, and a film. The die includes a semiconductor substrate, a metallization structure on the semiconductor substrate, and a dielectric material around at least a part of the metallization structure. The bonding layer is on the metallization structure. The film is attached on the bonding layer. The film includes a piezoelectric material.

In another example, a method includes forming a bonding layer on at least one of a metallization structure of a die or on a film. The method also includes attaching the film onto the metallization structure via the bonding layer.

### BRIEF DESCRIPTION OF THE DRAWINGS

FIG. 1 is cross-sectional view of an example circuit that includes a piezoelectric crystal layer attached to an integrated circuit.

FIG. 2 is cross-sectional view of a portion of the circuit of FIG. 1 showing electrical field flux between the electrodes of the integrated circuit.

FIG. 3 is a graph of admittance versus frequency in an example of the circuit of FIG. 1.

FIG. 4 is cross-sectional view of another example circuit that includes a piezoelectric crystal layer attached to an integrated circuit.

FIG. 5 is a cross-sectional view of an example circuit that includes multiple resonators formed by a piezoelectric crystal layer attached to an integrated circuit.

FIG. 6 is a block diagram of an example bandpass filter including multiple resonators of the circuit of FIG. 5.

FIG. 7 is a graph of admittance versus frequency in an example resonator of the circuit of FIG. 5.

FIG. 8 is a graph of example performance of the bandpass filter of FIG. 6.

FIG. 9 is a schematic of an example radio frequency receiver circuit that includes an example of the bandpass filter of FIG. 6.

FIG. 10 is a block diagram of an example oscillator circuit that includes an example of a resonator using a piezoelectric crystal layer attached to an integrated circuit.

FIG. 11 is a flow diagram of an example method for fabricating a circuit that includes a piezoelectric crystal layer attached to an integrated circuit.

FIGS. 12A-12K are cross-sectional views of the various fabrication steps of the method of FIG. 11.

FIGS. 13A and 13B are perspective views of example alignment of a piezoelectric crystal layer with an integrated circuit.

### DETAILED DESCRIPTION

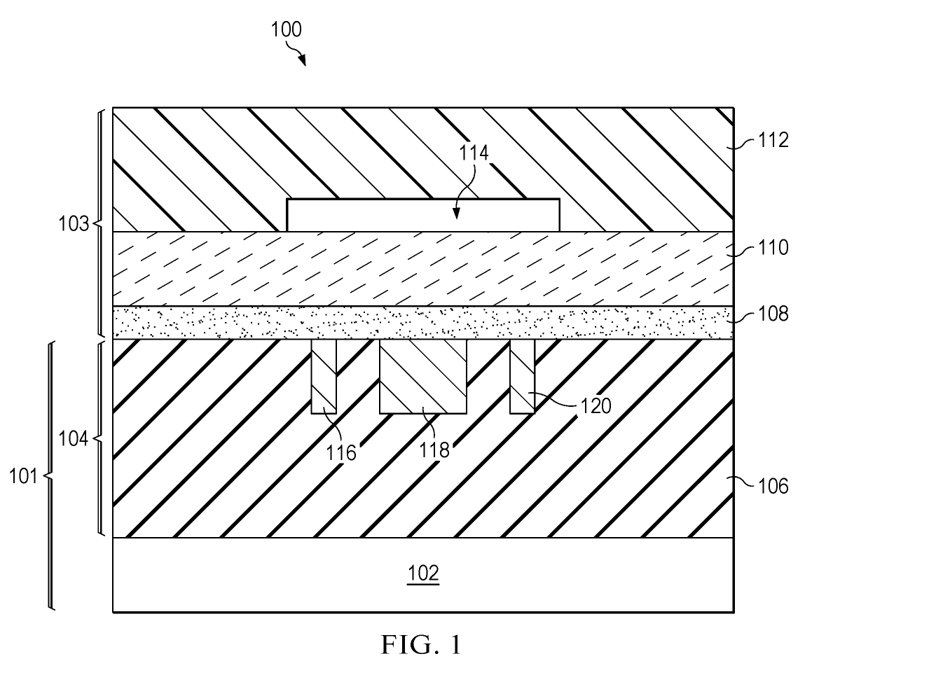

FIG. 1 is cross-sectional view of an example circuit 100 that includes a resonator 103 attached to an integrated circuit 101. The integrated circuit 101 includes a semiconductor substrate 102 and a metallization structure 104 on the semiconductor substrate 102. The semiconductor substrate 102 can include complementary metal oxide semiconductor (CMOS) circuits, or circuits using another technology, and can include transistors and/or other electronic components that interact with the resonator 103 to provide a desired function. The metallization structure 104 includes an insulation material 106, such as silicon dioxide, and one or more metal layers in the insulation material 106. The metal layers can include copper, aluminum, or another suitable metal. The metal layers can interconnect components of the semiconductor substrate 102, and connect the integrated circuit 101 to the resonator 103, and to input/output terminals providing connection to external circuitry. The metallization structure 104 includes electrodes, provided in the metal layers, which couple the integrated circuit 101 to the resonator 103. The electrodes 116, 118, and 120 are shown in FIG. 1. The electrodes 116, 118, and 120 are laterally adjacent to one another, and may be positive electrodes or negative electrodes.

The resonator 103 includes a piezoelectric film 110, a bonding layer 108, and a cap 112. The piezoelectric film 110 is between the bonding layer 108 and the cap 112. The piezoelectric film 110 can include various piezoelectric materials, such as lithium niobate, aluminum nitride, or other materials. Certain piezoelectric film material, such as lithium niobate, has less defects and provides improved piezoelectric properties and electromechanical coupling effects, which allow resonator 103 to operate at a high frequency. However, it may be challenging to form piezoelectric film 110 on semiconductor substrate 102 in the environment where semiconductor substrate 102 is fabricated. For example, the material used to fabricate the piezoelectric film 110 may contaminate silicon and create defects in the electronic devices formed in the silicon, or the manufacturing environment (e.g., temperature) needed to produce the material of the piezoelectric film 110 may be incompatible with integrated circuit processing. Accordingly, as to be described herein, the material of the piezoelectric film 110 may be fabricated separately from the integrated circuit 101, which can allow the quality of the piezoelectric film 110 to be improved relative to materials that can be fabricated using processes compatible with the integrated circuit 101 and the processing used to fabricate integrated circuits.

The bonding layer 108 bonds the integrated circuit 101 and the resonator 103, such that the piezoelectric film 110 overlaps the electrodes 116, 118, and 120. The bonding layer 108 is provided on a first side of the piezoelectric film 110. The bonding layer 108 may include a bonding material such as a polymer, or other material suitable for bonding the integrated circuit 101 and the resonator 103. Suitable polymers can include parylene (e.g., parylene N or parylene C), polydimethylsiloxane (PDMS), etc. Other suitable bonding materials can also be used. The bonding layer 108 can be about 50 nanometers (nm) to 100 nm thick in various examples. Other bonding layer thicknesses may also be used. In some examples of the circuit 100, the bonding layer 108 can be provided as part of the integrated circuit 101.

The cap 112 is provided on a second side of the piezoelectric film 110. The cap 112 can be silicon or other suitable material. A portion of the cap 112 is thinned to provide an air gap 114 between the piezoelectric film 110 and the cap 112. The air gap 114 can improve acoustic transduction in the circuit 100. The air gap 114 can be about 10 nm or more in height in some examples.

Circuitry provided on the semiconductor substrate 102 is coupled to the electrodes 116, 118, and 120, and drive signals generated by circuitry are provided at the electrodes 116, 118, and 120. The drive signals excite an electric field in the piezoelectric film 110 through the electrodes to produce standing waves in the piezoelectric film 110. FIG. 2 is cross-sectional view of a portion of the circuit 100 showing the electrical field flux between the electrodes 116, 118, and 120. The electric fields are confined in the areas of piezoelectric film 110 between the electrodes 116, 118, and 120.

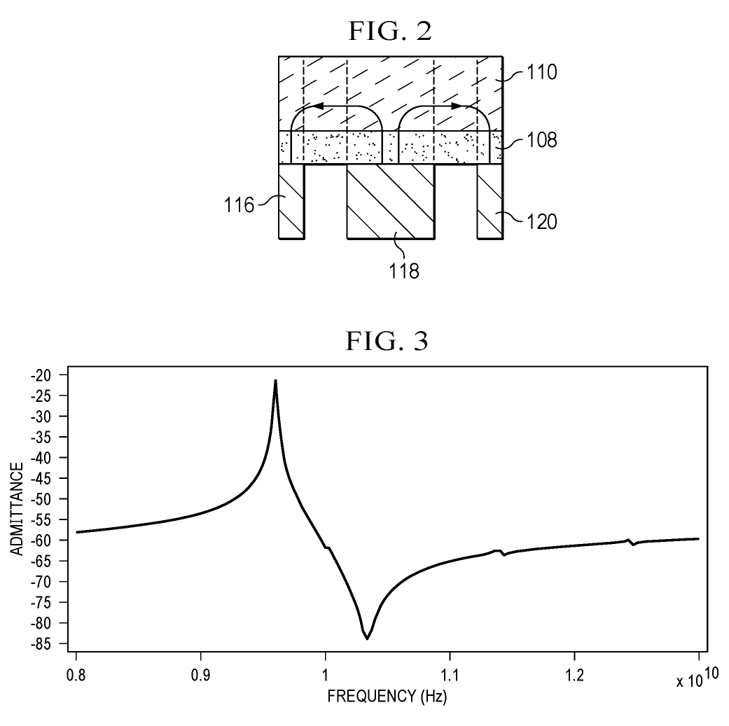

FIG. 3 is a graph of admittance versus frequency in an example of the circuit 100 showing electrostatic excitation of the piezoelectric film 110, with a coupling coefficient (k²) of about 19.5%. In this example of the circuit 100, the piezoelectric film 110 can be lithium niobate, and the bonding layer 108 can be 100 nm thick PDMS.

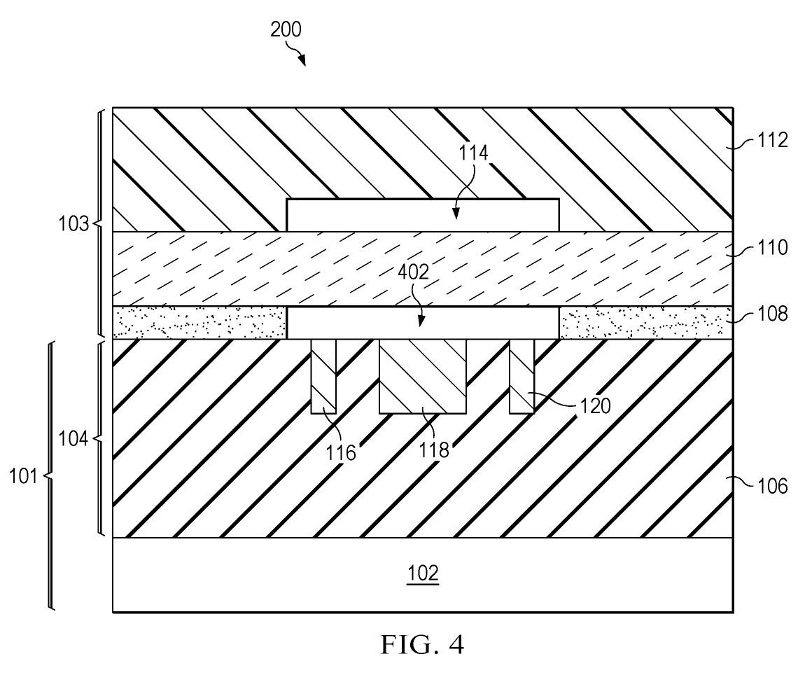

FIG. 4 is cross-sectional view of an example circuit 200 that includes the integrated circuit 101 attached to the resonator 103. The circuit 200 includes the integrated circuit 101 as described with reference to FIG. 1. The example of the resonator 103 used in the circuit 200, includes the bonding layer 108, the piezoelectric film 110, and the cap 112, and an opening is provided in the bonding layer 108 to form an air gap 402. The electrodes 116, 118, and 120 are spaced from the piezoelectric film 110 by the air gap 402. The piezoelectric film 110 is suspended in an air gap between the electrodes 116, 118, and 120, and the cap 112, which can improve the quality factor and coupling coefficient of the resonator.

The air gap 114 and the air gap 402 can be dimensioned so that the air gaps can be aligned with the electrodes 116, 118, and 120 to a relatively large tolerance. Accordingly, alignment of the integrated circuit 101 and the resonator 103 can be significantly simplified and can be performed in an environment that may lack high-precision alignment tools (e.g., in a packaging facility). The air gaps 114 and 402 can be filled with air or any suitable gas.

The materials and construction of the circuits 100 and 200 can produce high-Q resonators with a resonant frequency of 50 gigahertz and higher in some examples. Degradation due to bond wire inductance is avoided by using electrodes to electrostatically excite the piezoelectric film 110. The piezoelectric film 110 can include high-Q materials, such as lithium niobate, that may be difficult to process in integrated circuit fabrication, as explained above.

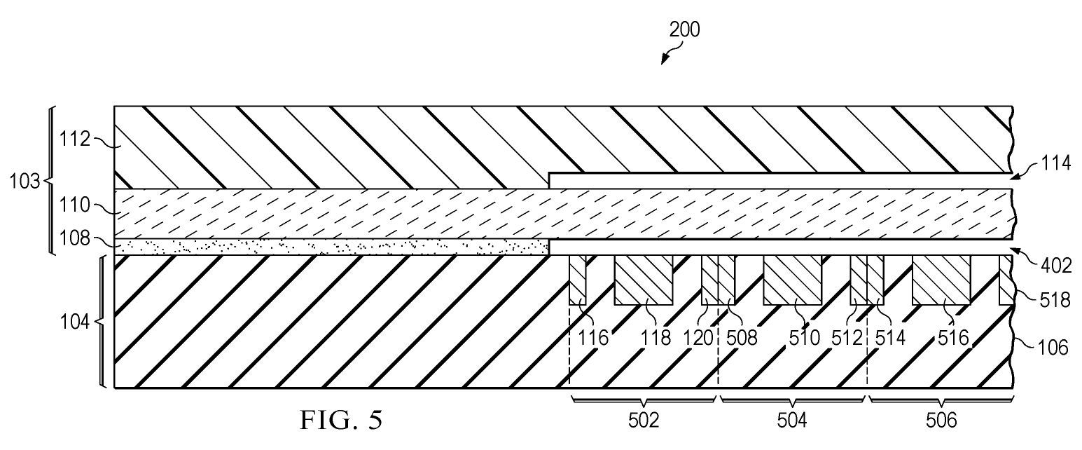

While FIGS. 1, 2, and 4 illustrate examples of a single resonator unit cell, the circuit 100 and circuit 200 may include any number of resonator unit cells. FIG. 5 is a cross-sectional view of an example circuit that includes multiple resonator unit cells. In FIG. 5, the metallization structure 104 includes resonator unit cells 502, 504, and 506. The resonator unit cell 502 includes electrodes 116, 118, and 120. The resonator unit cell 504 includes electrodes 508, 510, and 512. The resonator unit cell 506 includes electrodes 514, 516, and 518. As shown in FIG. 2, the electric field flux is a confined in the areas of the piezoelectric film 110 between the electrodes of each of the resonator unit cells 502, 504, and 506.

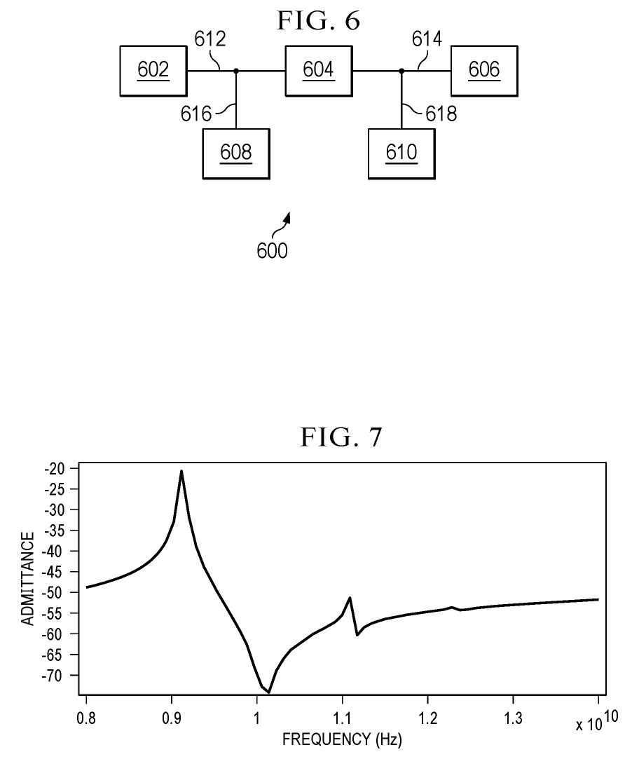

The metallization structure 104 can include metal conductors that connect the various resonator unit cells to form a circuit, or to provide a desired function. FIG. 6 is a block diagram of an example bandpass filter 600 including multiple resonators. The bandpass filter 600 includes resonators 602, 604, 606, 608, and 610, each of which can be a resonator unit cell as shown in FIG. 5, coupled via metal conductors of the metallization structure 104. The resonators 602, 604, and 606 are coupled in series by the metal conductors 612 and 614. The resonators 608 and 610 are coupled as shunts via the metal conductors 616 and 618. For example, a negative electrode of the resonator 602 is coupled to a positive electrode of the resonator 604 via the metal conductor 612, and to a positive electrode of the resonator 608 via the metal conductor 616. A negative electrode of the resonator 604 is coupled to a positive electrode of the resonator 606 via the metal conductor 614, and to a positive electrode of the resonator 610 via the metal conductor 618. A positive electrode of the resonator 602 can serve as a signal input terminal for the filter, and a negative electrode of the resonator 606 can serve as a signal output terminal for the filter. Negative electrodes of the resonator 608 and the resonator 610 can be connected to a reference terminal, such as ground.

FIG. 7 is a graph of admittance versus frequency in an example resonator 602, 604, or 606 of the bandpass filter 600. These filters can be implemented as the resonator unit cells 502, 504, and 506 of FIG. 5. In FIG. 7, the air gaps 114 and 402 can be about 10 nm in height, and the resonator has a coupling coefficient (k²) of about 28.6%.

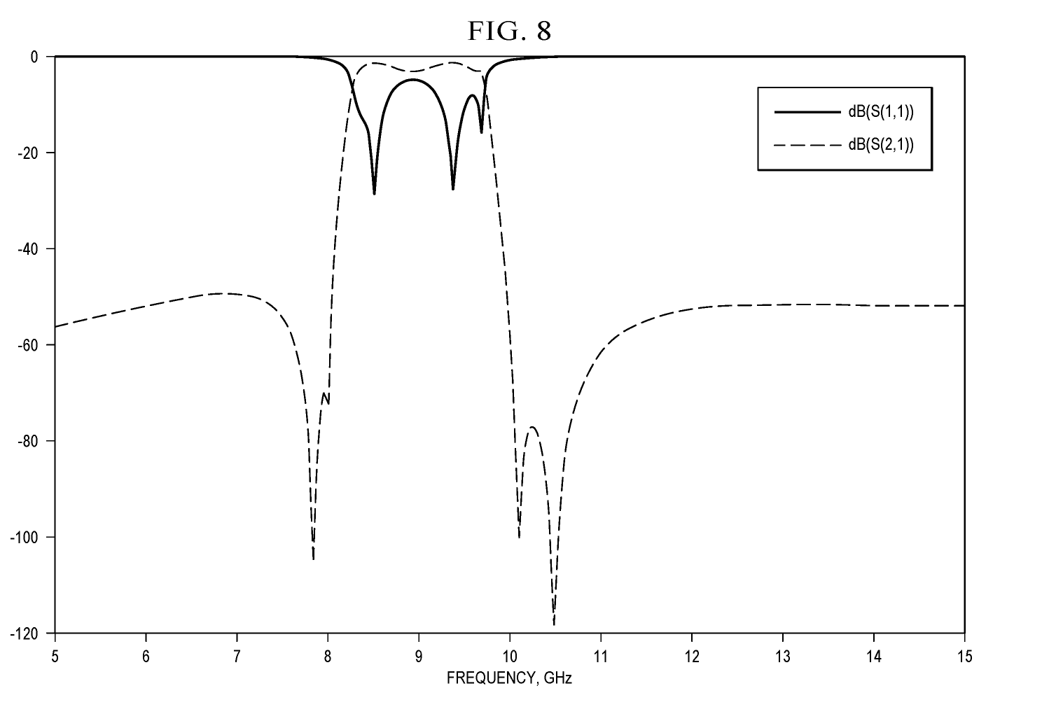

FIG. 8 is a graph of example performance of the bandpass filter of FIG. 6. FIG. 8 shows the reflection coefficient S₁₁ and the forward voltage gain S₂₁ of an example of the bandpass filter 600. In FIG. 8, the bandpass filter 600 has a center frequency of about 9.125 GHz, fractional bandwidth of about 19.2%, out-of-band rejection of about 48 decibels (dB), a minimum input level of about 1 dB, and passband ripple of about 1.5 dB.

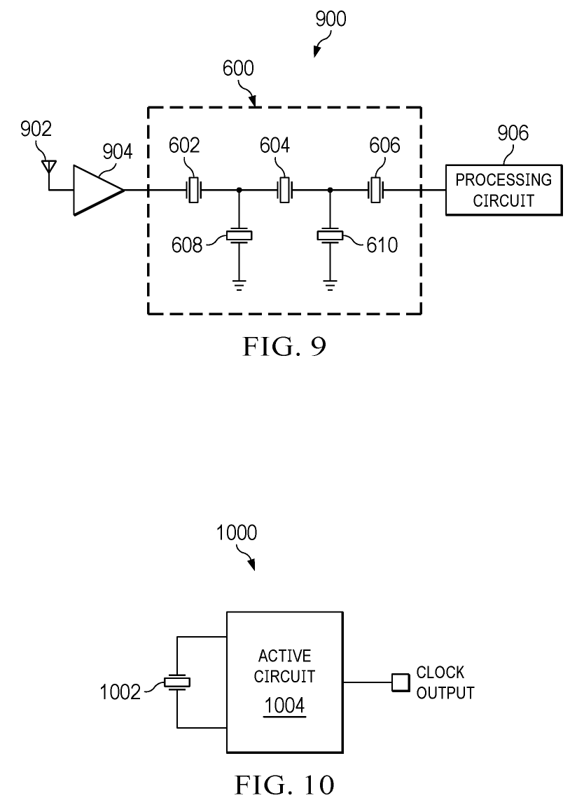

FIG. 9 is a schematic of an example radio frequency receiver circuit 900 that includes an example of the bandpass filter 600. The radio frequency receiver circuit 900 also includes an antenna 902, an amplifier 904, and a processing circuit 906. The antenna 902 is coupled to an input of the amplifier 904, and an output of the amplifier 904 is coupled to an input of the bandpass filter 600 (e.g., the positive electrode of the resonator 602). An output of the bandpass filter 600 (e.g., a negative terminal of the resonator 606) is coupled to an input of the processing circuit 906. The bandpass filter 600 attenuates out of band frequencies in the radio frequency signals received from the antenna. The processing circuit 906 processes (e.g., demodulates and decodes) the filtered radio frequency signals to extract information. The amplifier 904 and/or the processing circuit 906 can be implemented in the semiconductor substrate 102.

FIG. 10 is a block diagram of an example oscillator circuit 1000. The oscillator circuit 1000 includes a resonator 1002 and an active circuit 1004. The resonator 1002 is coupled to the active circuit 1004. For example, positive and negative electrodes of the resonator 1002 are driven by the active circuit 1004. The active circuit 1004 has an output at which a clock signal having a frequency derived from the resonant frequency of the resonator 1002 is provided. The resonator 1002 and the active circuit 1004 can be implemented as examples of the circuit 100 or the circuit 200. The active circuit 1004 can be implemented in the semiconductor substrate 102, and the resonator 1002 can be implemented in the resonator 103 and the metallization structure 104.

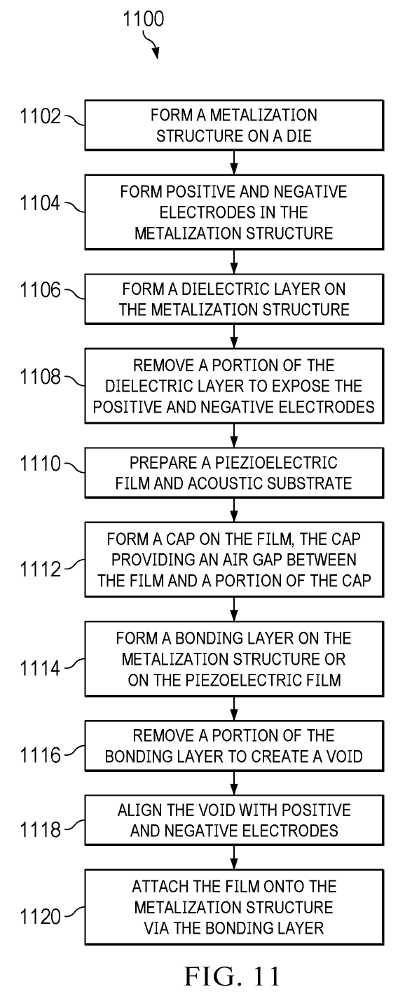

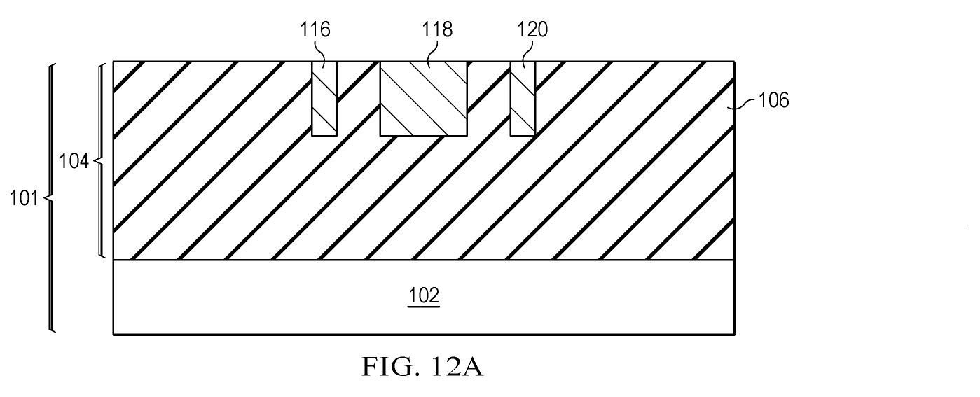

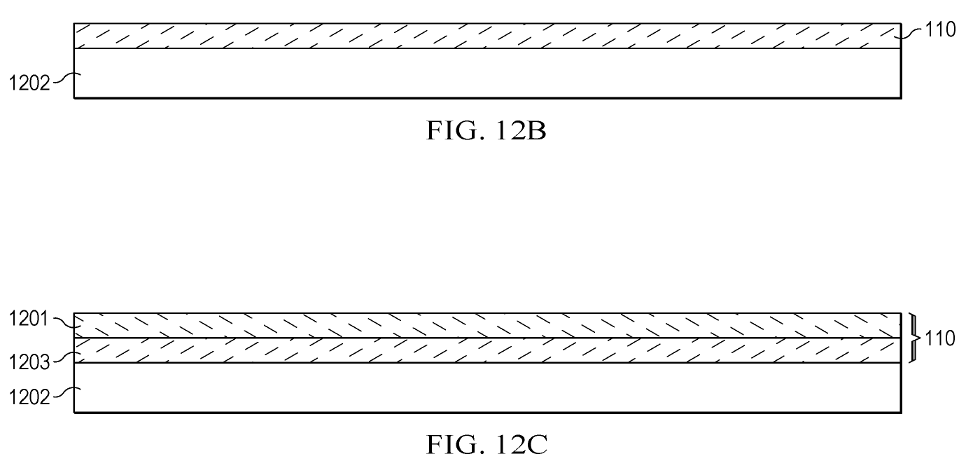

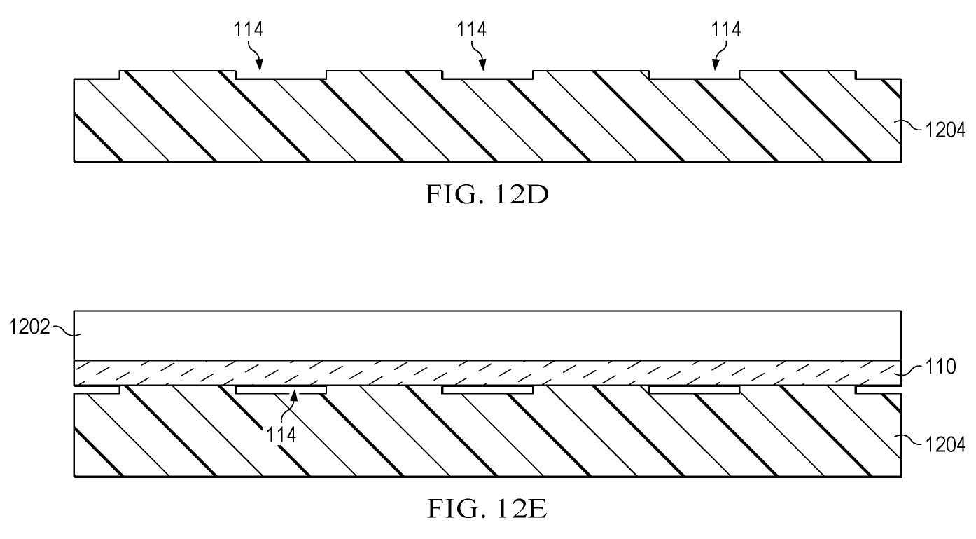

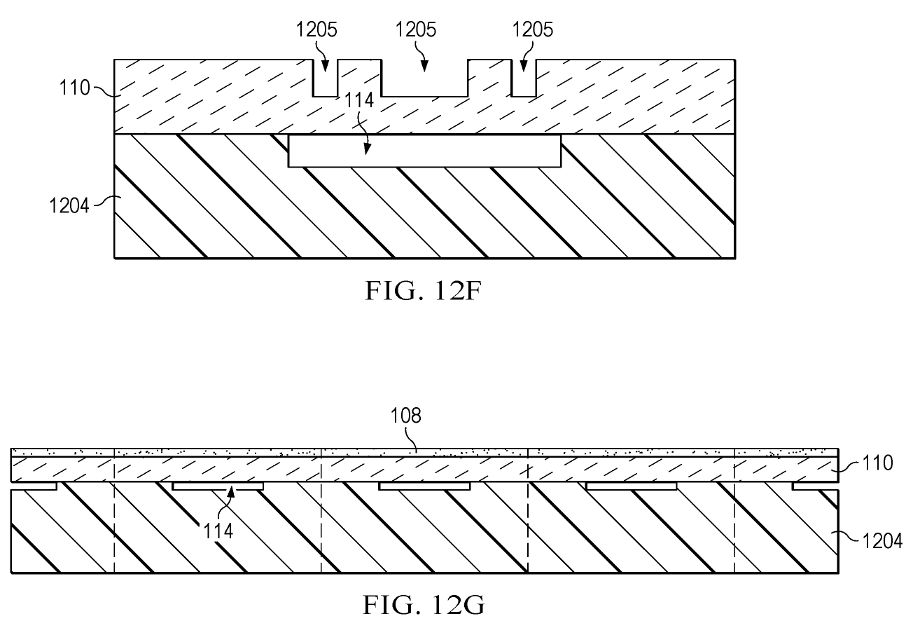

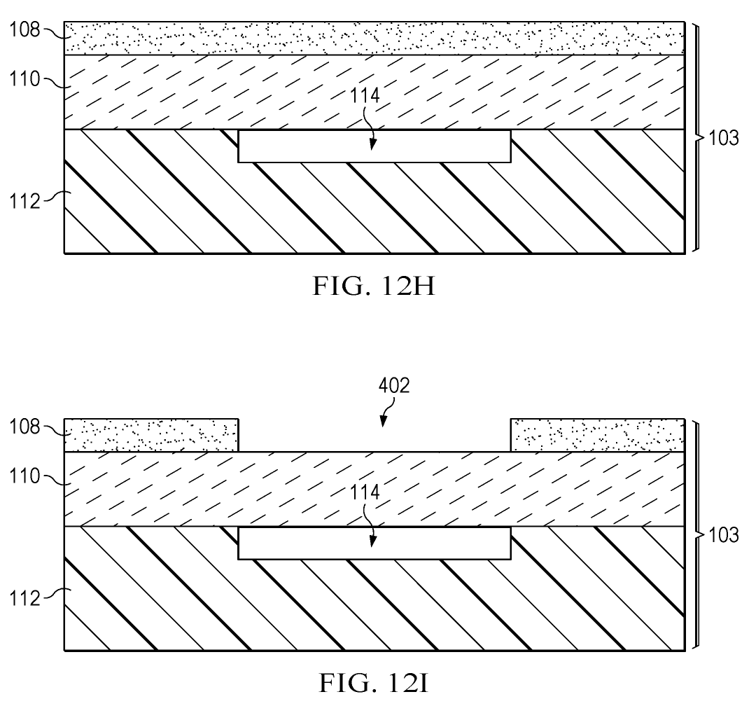

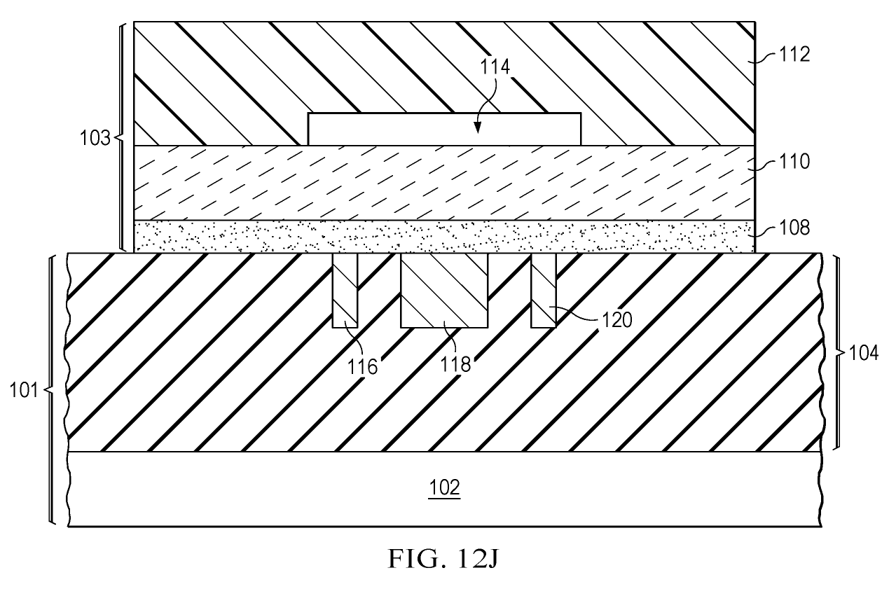

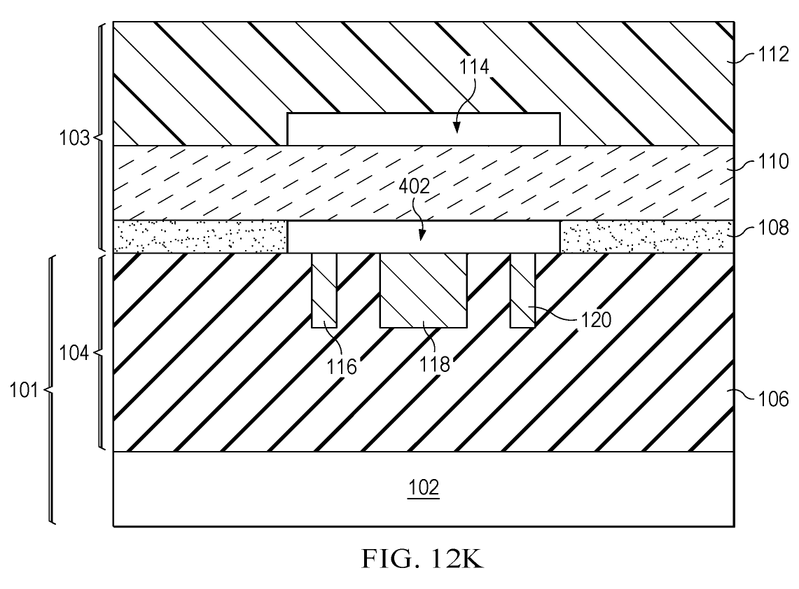

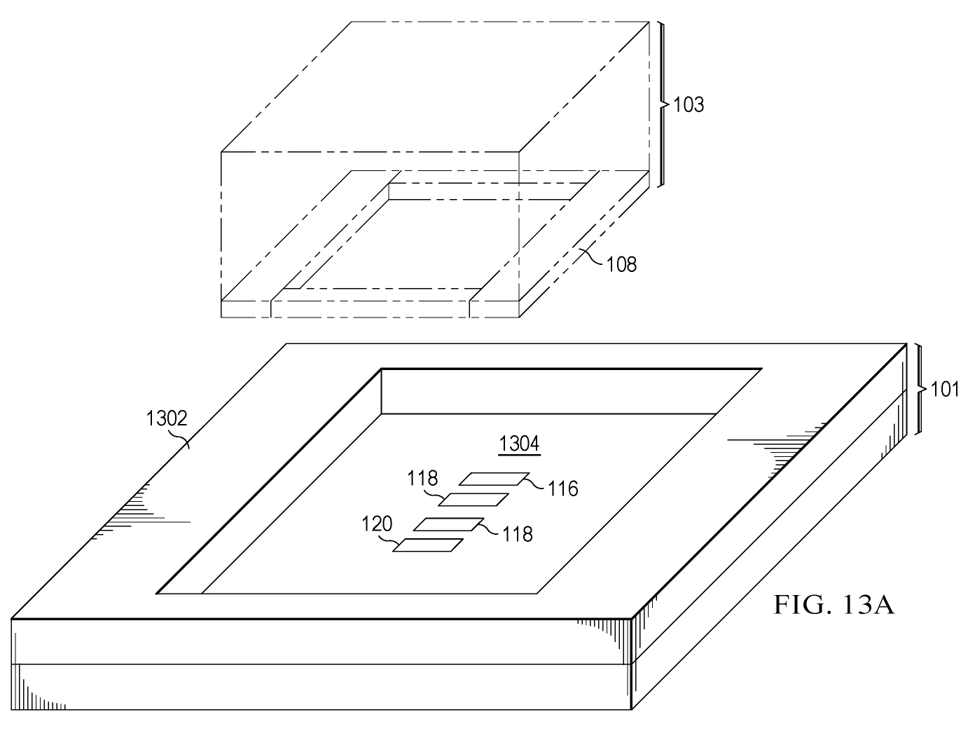

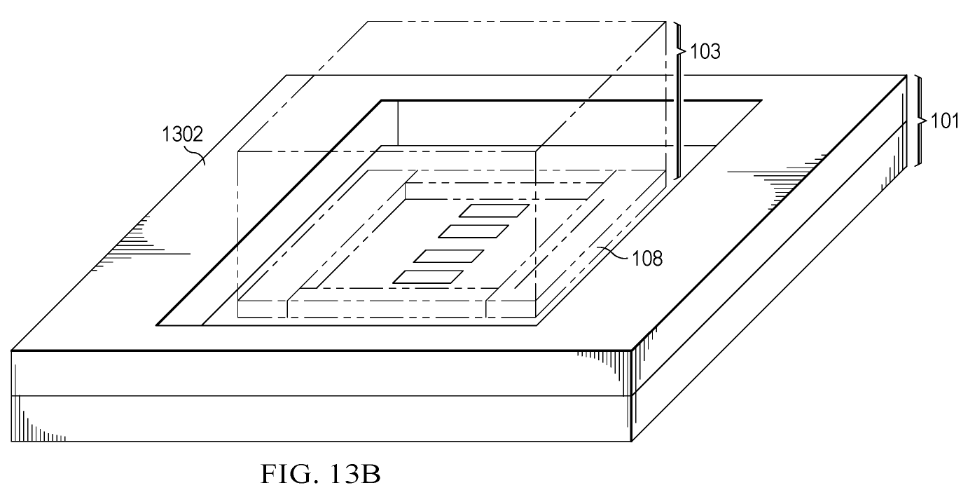

FIG. 11 is a flow diagram of an example method 1100 for fabricating a circuit that includes a piezoelectric crystal layer attached to an integrated circuit. Though depicted sequentially as a matter of convenience, at least some of the actions shown can be performed in a different order and/or performed in parallel. Additionally, some implementations may perform only some of the actions shown. The method 1100 can be used to fabricate examples of the circuit 100 or the circuit 200. Operations of the method 1100 are illustrated in FIGS. 12A-12K, and FIGS. 13A and 13B.

Prior to the operations of block 1102, the semiconductor substrate 102 is prepared in an integrated circuit fabrication facility (e.g., a CMOS IC fabrication facility), and electronic components are fabricated on the semiconductor substrate 102. The piezoelectric film 110 can be prepared in a facility that is separate from the integrated circuit manufacturing facility. The piezoelectric film 110 can be prepared in a facility that is suitable for manufacturing piezoelectric materials (e.g., piezoelectric materials having a single crystalline structure), such as lithium niobate crystal.

In block 1102, the metallization structure 104 is fabricated on the semiconductor substrate 102. The metallization structure 104 can be fabricated in back-end-of-line (BEOL) processing performed as part of integrated circuit packaging. The metallization structure 104 can include any number of dielectric (e.g., silicon dioxide) and metal layers (e.g., copper or aluminum) as needed to interconnect the components provided by the semiconductor substrate 102, and to provide external connection terminals.

In block 1104, the electrodes 116, 118, and 120 (and any other electrodes that can be used to drive the piezoelectric film 110) are fabricated in the metallization structure 104. The metal structures of the metallization structure 104 including the electrodes, can be fabricated using a damascene process.

In block 1106, a layer of dielectric material, such as silicon dioxide, is formed on the metallization structure.

In block 1108, a portion of the dielectric layer formed in block 1106 is removed to expose the electrodes 116, 118, and 120. FIG. 12A shows an example of the metallization structure 104 fabricated on the semiconductor substrate 102 after the electrodes have been exposed. FIG. 13A shows a dielectric layer 1302 on the metallization structure etched to form and opening 1304 exposing the electrodes 116, 118, and 120.

In block 1110, the piezoelectric film 110 is fabricated and bonded to an acoustic substrate 1202. The piezoelectric film 110 can be fabricated in a facility that is separate from the integrated circuit manufacturing facility in which the semiconductor substrate 102 is fabricated. The piezoelectric film 110 can be lithium niobate, aluminum nitride, or any other piezoelectric material. The piezoelectric film 110 can have a single crystalline structure or a polycrystalline structure. A single crystal film can be provided with a variety of wafer orientations to provide a desired acoustic performance. Because the piezoelectric film 110 is fabricated separately from (e.g., in a different facility from) the semiconductor substrate 102, fabrication of the piezoelectric film 110 does not contaminate the semiconductor substrate 102 (e.g. lithium used to fabricate the piezoelectric film 110 does not contaminate the silicon of the semiconductor substrate 102), and the piezoelectric film 110 can be fabricated with higher quality than would be possible in an integrated circuit fabrication facility. The material of the acoustic substrate 1202 may be selected based on the piezoelectric film 110. The material of the acoustic substrate 1202 can be quartz, lithium niobate, sapphire, silicon, aluminum nitride, or other materials. FIG. 12B shows an example of the piezoelectric film 110 bonded to the acoustic substrate 1202. Examples of the piezoelectric film 110 can include one or more layers of piezoelectric crystal, where the orientation of the crystal of each layer can be selected to produce a desired resonant frequency. FIG. 12C shows an example of the piezoelectric film 110 that includes a piezoelectric crystal layer 1201 and a piezoelectric crystal layer 1203. The crystal(s) of the piezoelectric crystal layer 1201 can have the same orientation as the crystal(s) of the piezoelectric crystal layer 1203, or different orientation from the crystal(s) of the piezoelectric crystal layer 1203, to provide a desired resonant frequency.

In block 1112, a silicon cap wafer 1204 is prepared and bonded to the piezoelectric film 110. The silicon cap wafer 1204 provides the air gap 114. FIG. 12D shows an example of the silicon cap wafer 1204. The silicon cap wafer 1204 is bonded to the piezoelectric film 110. FIG. 12E shows the silicon cap wafer 1204 bonded to the piezoelectric film 110. After the silicon cap wafer 1204 is bonded to the piezoelectric film 110, the acoustic substrate 1202 can be removed.

After the acoustic substrate 1202 has been removed, recesses can be formed in some examples of the piezoelectric film 110. The recesses can be positioned such that the electrodes 116, 118, and 120 are each aligned with one of the recesses. The recesses can improve energy confinement in the piezoelectric film 110, and increase the quality factor of the resonator. FIG. 12F shows recesses 1205 formed in the piezoelectric film 110 above the air gap 114. The recesses 1205 can be formed by etching the piezoelectric film 110.

After the acoustic substrate has been removed, in block 1114, a bonding layer 108 is formed on the piezoelectric film 110 in place of the acoustic substrate 1202. For example, the bonding layer 108 can be formed on the piezoelectric film 110 as shown in FIG. 12E or FIG. 12F. The bonding layer 108 can be a polymer, silicon dioxide, or other material. In some examples, the bonding layer 108 can be formed on the metallization structure 104.

The silicon cap wafer 1204 can be subdivided (singulated) into individual examples of the resonator 103 for bonding to the integrated circuit 101. FIG. 12G shows the silicon cap wafer 1204 and the lines along which the resonator 103 can be singulated from the silicon cap wafer 1204. FIG. 12H shows an example of the resonator 103 singulated from the silicon cap wafer 1204.

In block 1116, a portion of the bonding layer 108 can be removed from the resonator 103 to form a void in some examples. The portion of the bonding layer 108 removed can be aligned with air gap 114, and form the air gap 402 between the piezoelectric film 110 and the electrodes 116, 118, and 120. FIG. 12I shows an example of the resonator 103 after removal of a portion of the bonding layer 108 to form the air gap 402.

In block 1118, the resonator 103 is aligned with the electrodes 116, 118, and 120. If the resonator 103 includes the recesses 1205, the recesses 1205 are aligned with the electrodes 116, 118, and 120. If the resonator 103 lacks the recesses 1205, then the alignment of the resonator 103 with the electrodes 116, 118, and 120 can be relatively imprecise because the air gaps 114 and 402 can be dimensioned to allow for imprecise alignment of the resonator 103 relative to the electrodes 116, 118, and 120. For example, the only constraint to alignment may be that the air gaps 114 and 402 are located above the electrodes 116, 118, and 120. Also, misalignment of silicon cap wafer 1204 with piezoelectric film 110, such that lateral air gaps are created laterally adjacent to piezoelectric film 110 (and resonator 103) within the opening 1304, does not degrade the performance of resonator 103, at least because lateral air gaps do not impact energy confinement. In FIG. 13A, proper alignment of the resonator 103 with the electrodes 116, 118, and 120 can be achieved by placing the resonator 103 anywhere within the opening 1304.

In block 1120, the piezoelectric film 110 is attached to the metallization structure 104 via the bonding layer 108. FIGS. 12J and 12K show cross-sectional views of examples of the resonator 103 attached to the metallization structure 104. FIG. 12J shows the resonator 103 of FIG. 12H attached to the metallization structure 104. FIG. 12K shows the resonator 103 of FIG. 12I attached to the metallization structure 104. FIG. 13B shows a perspective view of the resonator 103 attached to the integrated circuit 101.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

Circuits described herein are reconfigurable to include additional or different components to provide functionality at least partially similar to functionality available prior to the component replacement.

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/- 10 percent of that parameter or, if the parameter is zero, a reasonable range of values around zero.

Modifications are possible in the described embodiments, and other embodiments are possible, within the scope of the claims.

What is claimed is:

1. An apparatus comprising:
a die including a semiconductor substrate, a metallization structure on the semiconductor substrate, and a dielectric material around at least a part of the metallization structure;
a bonding layer on the metallization structure; and
a film attached on the bonding layer, the film including a piezoelectric material.

2. The apparatus of claim 1, wherein the piezoelectric material includes at least one of: Aluminum Nitride or Lithium Niobate.

3. The apparatus of claim 1, wherein the bonding layer includes a bonding material, and the bonding material includes at least one of a polymer or a dielectric material.

4. The apparatus of claim 3, wherein the bonding material includes at least one of: parylene, PDMS, or silicon dioxide.

5. The apparatus of claim 3, wherein the piezoelectric material has a single crystalline structure.

6. The apparatus of claim 1, wherein the metallization structure includes a positive electrode and a negative electrode, the positive electrode and the negative electrode being laterally adjacent to each other.

7. The apparatus of claim 6, wherein the film overlaps the positive electrode and the negative electrode.

8. The apparatus of claim 6, further comprising a cap on the film, in which a part of the cap above the positive electrode and the negative electrode is separated from a part of the film by a first gap.

9. The apparatus of claim 8, wherein the part of the film is also spaced from the positive electrode and the negative electrode by a second gap, in which the second gap is free of the bonding layer.

10. The apparatus of claim 7, wherein:
the positive electrode is a first positive electrode, and the negative electrode is a first negative electrode;
the metallization structure includes a second positive electrode, a second negative electrode, a third positive electrode, and a third negative electrode that are laterally adjacent to each other;
the first positive electrode is coupled to a signal input terminal, and the third negative electrode is coupled to a signal output terminal;
the first negative electrode is coupled to the second positive electrode and the third positive electrode; and
the second negative electrode is coupled to a reference terminal.

11. The apparatus of claim 7, wherein the film, the positive electrode, and the negative electrode are configured as a piezoelectric resonator, and the semiconductor substrate includes transistors electrically coupled to the piezoelectric resonator via metal conductors of the metallization structure.

12. The apparatus of claim 11, wherein the transistors include a first half-bridge having a first switching terminal and a second half-bridge having a second switching terminal, and the piezoelectric resonator is coupled between the first and second switching terminals.

13. A method comprising:
forming a bonding layer on at least one of a metallization structure of a die or on a film; and
attaching the film onto the metallization structure via the bonding layer.

14. The method of claim 13, further comprising forming a positive electrode and a negative electrode that are laterally adjacent to each other in the metallization structure.

15. The method of claim 14, further comprising forming a cap on the film, the cap providing an air gap between a portion of the cap and the film.

16. The method of claim 15, further comprising:
forming a dielectric layer on the metallization structure;
removing a portion of the dielectric layer to form an opening in which the positive electrode and the negative electrode are exposed; and
placing the bonding layer, the film, and the cap in the opening.

17. The method of claim 15, further comprising placing the bonding layer, the film, and the cap on the metallization structure.

18. The method of claim 17, wherein the film is between the air gap and positive and negative electrodes.

19. The method of claim 17, further comprising removing a portion of the bonding layer to create a void in the bonding layer.

20. The method of claim 19, further comprising aligning the void in the bonding layer with the positive electrode and the negative electrode.
